(19) United States
(12) Patent Application Publication
(10) Pub. No.: US 2008/0210304 A1
(43) Pub. Date: Sep. 4, 2008

(54) Photovoltaic Cell Comprising a Photovotaically Active Semi-Conductor Material Contained Therein

(75) Inventor: Hans-Josef Sterzel, Dannstadt-Schauernheim (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF SE, Ludwigshafen (DE)

(21) Appl. No.: 12/088,859

(22) PCT Filed: Sep. 29, 2006
(86) PCT No.: PCT/EP2006/066895

§ 371 Date: Apr. 1, 2008

(30) Foreign Application Priority Data
Oct. 6, 2005 (DE) 102005047907.3

(51) Int. Cl. H01L 31/0264; H01L 31/18

(52) U.S. Cl. 136/261; 136/265; 438/94; 257/E31.004

(57) ABSTRACT

The invention relates to a photovoltaic cell comprising a photovoltaically active semiconductor material, wherein the photovoltaically active semiconductor material is a material of the formula (I), of the formula (II) or of a combination thereof:

(Zn₁₋ₓMgₓTe)_{1-y}(MₙTeₘ)_{y} and (I)

(ZnTe)_{1-y}(MeₐM_{b})_{y}, where (II)

MₙTeₘ and MeₐM_{b} are each a dopant in which M is at least one element selected from the group consisting of Si, Ge, Sn. Pb, Sb and Bi and Me is at least one element selected from the group consisting of mg and Zn, and
x=0 to 0.5
y=0.0001 to 0.05
n=1 to 2
m=0.5 to 4
a=1 to 5 and
b=1 to 3.

The invention relates to photovoltaic cells and the photovoltaically active semiconductor material present therein.

Photovoltaically active materials are semiconductors which convert light into electric energy. The principles of this have been known for a long time and are utilized industrially. Most of the solar cells used industrially are based on crystalline silicon (single-crystal or polycrystalline). In a boundary layer between p- and n-conducting silicon, incident photons excite electrons of the semiconductor so that they are raised from the valence band to the conduction band.

The magnitude of the energy gap between the valence band and the conduction band limits the maximum possible efficiency of the solar cell. In the case of silicon, this is about 30% on irradiation with sunlight. In contrast, an efficiency of about 15% is achieved in practice because some of the charge carriers recombine by various processes and are thus no longer effective.

DE 102 23 744 A1 discloses alternative photovoltaically active materials and photovoltaic cells in which these are present, which have the loss mechanisms which reduce efficiency to a lesser extent.

With an energy gap of about 1.1 eV, silicon has quite a good value for practical use. A decrease in the energy gap will push more charge carriers into the conduction band, but the cell voltage becomes lower. Analogously, larger energy gaps would result in higher cell voltages, but because fewer photons are available to be excited, lower usable currents are produced.

Many arrangements such as series arrangement of semiconductors having different energy gaps in tandem cells have been proposed in order to achieve higher efficiencies. However, these are very difficult to realize economically because of their complicated structure.

A new concept comprises generating an intermediate level within the energy gap (up-conversion). This concept is described, for example, in Proceedings of the 14^{th} Workshop on Quantum Solar Energy Conversion-Quantasol 2002, Mar. 17-23, 2002, Rauris, Salzburg, Austria, “Improving solar cells efficiencies by the up-conversion”, T I. Trupke, M. A. Green, P. Würfel or “Increasing the Efficiency of Ideal Solar Cells by Photon Induced Transitions at intermediate Levels”, A. Luque and A. Marti, Phys. Rev. Letters, Vol. 78, No. 26, June 1997, 5014-5017. In the case of a band gap of 1.995 eV and an energy of the intermediate level of 0.713 eV, the maximum efficiency is calculated to be 63.17%.

Such intermediate levels have been confirmed spectroscopically, for example in the system Cd_{1-y}Mn_{y}OₓTe₁₋ₓ or Zn₁₋ₓMnₓO_{y}Te_{1-y}. This is described in “Band anticrossing in group II-OₓVI₁₋ₓ highly mismatched alloys: Cd_{1-y}Mn_{y}OₓTe₁₋ₓ quaternaries synthesized by O ion implantation”, W. Walukiewicz et al., Appl. Phys. Letters, Vol 80, No. 9, March 2002, 1571-1573, and in “Synthesis and optical properties of II-O-VI highly mismatched alloys”, W. Walukiewicz et al., Appl. Phys. Vol 95, No. 11, June 2004, 6232-6238. According to these authors, the desired intermediate energy level in the band gap is raised by part of the tellurium anions in the anion lattice being replaced by the significantly more electronegative oxygen ion. Here, tellurium was replaced by oxygen by means of ion implantation in thin films. A significant disadvantage of this class of materials is that the solubility of oxygen in the semiconductor is extremely low. This results in, for example, the compounds Zn₁₋ₓMnₓTe_{1-y}O_{y} in which y is greater than 0.001 being thermodynamically unstable. On irradiation over a prolonged period, they decompose into the stable tellurides and oxides. Replacement of up to 10 atom % of tellurium by oxygen would be desirable, but such compounds are not stable.

Zinc telluride, which has a direct band gap of 2.25 eV at room temperature, would be an ideal semiconductor for the intermediate level technology because of this large band gap. Zinc in zinc telluride can readily be replaced continuously by manganese, with the band gap increasing to about 3.4 eV for MgTe (“Optical Properties of epitaxial ZnMnTe and ZnMgTe films for a wide range of alloy compositions”, X. Liu et al., J. Appl. Phys. Vol. 91, No. 5, March 2002, 2859-2865; “Bandgap of Zn₁₋ₓMnₓTe: non linear dependence on composition and temperature”, H. C. Mertins et al., Semicond. Sci. Technol. 8 (1993) 1634-1638).

A photovoltaic cell usually comprises a p-conducting absorber and an n-conducting transparent layer comprising, for example, indium-tin oxide, fluorine-doped tin oxide, antimony-doped zinc oxide or aluminum-doped zinc oxide.

An absorber having an intermediate level in the energy gap is obtained by, for example, introducing metal halides of the metals germanium, tin, antimony, bismuth or copper into a semiconductor material of the formula ZnTe and/or Zn₁₋ₓMnₓTe, where x=0.01-0.7, in amounts of preferably from 0.005 to 0.05 mol per mol of telluride.

The partial replacement of tellurium in the semiconductor lattice by the more electronegative halide ions obviously results in formation of the desired stable intermediate energy level in the band gap.

It is an object of the present invention to provide a photovoltaic cell which has a high efficiency and a high electric power. A further object of the present invention is to provide, in particular, a photovoltaic cell comprising an alternative thermodynamically stable photovoltaically active semiconductor material which comprises an intermediate level in the energy gap.

This object is achieved according to the invention by a photovoltaic cell comprising a photovoltaically active semiconductor material, wherein the photovoltaically active semiconductor material is a material of the formula (I), of the formula (II) or of a combination thereof:

(Zn₁₋ₓMgₓTe)_{1-y}(MₙTeₘ)_{y} and (I)

(ZnTe)_{1-y}(MeₐM_{b})_{y}, where (II)

MₙTeₘ and MeₐM_{b} re each a dopant in which M is at least one element selected from the group consisting of silicon, germanium, tin, lead, antimony and bismuth and Me is at least one element selected from the group consisting of magnesium and zinc, and
x=0 to 0.5
y=0.0001 to 0.05
n=1 to 2
m=0.5 to 4
a=1 to 5
b=1 to 3.

The invention further provides a photovoltaically active semiconductor material of the formula (I), of the formula (II) or of a combination thereof:

(Zn₁₋ₓMgₓTe)_{1-y}(MₙTeₘ)_{y} and (I)

(ZnTe)_{1-y}(MeₐM_{b})_{y}, where (II)

MₙTeₘ and MeₐM_{b} are each a dopant in which M is at least one element selected from the group consisting of silicon, germanium, tin, lead, antimony and bismuth and Me is at least one element selected from the group consisting of magnesium and zinc, and
x=0 to 0.5
y=0.0001 to 0.05
n=1 to 2
m=0.5 to 4
a=1 to 5 and
b=1 to 3.

Completely surprisingly, it has been found that the incorporation of halide ions can be dispensed with when tellurides of the formula (I) or (II) or combinations thereof are used.

It is assumed that the tellurides mentioned interact with the metal ions M=Si, Ge, Sn, Pb, Sb and/or Bi in the crystal lattice in such a way that they are negatively polarized in the vicinity of Zn²⁺ ions and are positively polarized in the vicinity of Te²⁻ ions, for example
2+ δ− δ+ 2−
Zn . . . SB Sb . . . Te
   and the desired intermediate energy level is formed as a result. Magnesium appears to reinforce this effect because it is more electronegative than zinc.

In a preferred embodiment of the present invention, the dopant (MₙTeₘ or MeₐM_{b}) s at least one compound selected from the group consisting of Si₃Te₃, GeTe, SnTe, PbTe, Sb₂Te₃, Bi₂Te₃, Mg₂Si, Mg₂Ge, Mg₂Sn, Mg₂Pb, Mg₃Sb₂, Mg₃Bi₂, ZnSb, Zn₃Sb₂ and Zn₄Sb₃.

For example, Sb₂Te₃ as a pure substance has a band gap of 0.3 eV. If ZnTe is doped with 2 mol % of Sb₂Te₃, an absorption is found at 0.8 eV in addition to the band gap of ZnTe at 2.25-2.3 eV.

Combinations of the dopants mentioned are also possible.

The semiconductor materials used in the photovoltaic cell of the invention surprisingly have high Seebeck coefficients up to 100 μV/degree together with a high electrical conductivity. This behavior shows that the novel semiconductors can be activated not only optically but also thermally and thus contribute to better utilization of light quanta.

The photovoltaic cell of the invention has the advantage that the photovoltaically active semiconductor material of the formula (I), of the formula (II) or of a combination thereof which is used is thermodynamically stable. Furthermore, the photovoltaic cells of the invention have high efficiencies above 15%, since the dopants present in the semiconductor material produce an intermediate level in the energy gap of the photovoltaically active semiconductor material. Without an intermediate level, only photons having at least the energy of the energy gap could raise electrons or charge carriers from the valence band into the conduction band. Photons having a higher energy also contribute to the efficiency, with the excess energy compared to the band gap being lost as heat. In the case of the intermediate level which is present in the semiconductor material used according to the present invention and can be partly occupied, more photons can contribute to excitation.

The photovoltaic cell of the invention preferably comprises a p-conducting absorber layer comprising the material of the formula (I), of the formula (II) or of a combination thereof. This absorber layer comprising the p-conducting semiconductor material is adjoined by an n-conducting contact layer which preferably does not absorb the incident light, preferably an n-conducting transparent layer which comprises at least one semiconductor material selected from the group consisting of indium-tin oxide, fluorine-doped tin oxide, antimony-doped, gallium-doped, indium-doped and aluminum-doped zinc oxide. Incident light generates a positive charge and a negative charge in the p-conducting semiconductor layer. The charges diffuse in the p region. Only when the negative charge reaches the p-n boundary can it leave the p region. A current flows when the negative charge has reached the front contact applied to the contact layer.

In a preferred embodiment of the photovoltaic cell of the invention, it comprises an electrically conductive substrate, a p layer of the semiconductor material of the invention of the formula (I) and/or (II) having a thickness of from 0.1 to 20 μm, preferably from 0.1 to 10 μm, particularly preferably from 0.3 to 3 μm, and an n layer of an n-conducting semiconductor material having a thickness of from 0.1 to 20 μm, preferably from 0.1 to 10 μm, particularly preferably from 0.3 to 3 μm. The substrate is preferably a glass pane coated with an electrically conductive material, a flexible metal foil or a flexible metal sheet. A combination of a flexible substrate with thin photovoltaically active layers gives the advantage that no complicated and thus expensive support has to be used for holding the solar module comprising the photovoltaic cells of the invention. The flexibility makes warping possible, so that very simple and inexpensive support constructions which do not have to be stiff enough to resist warping can be used. In particular, a stainless steel sheet is used as preferred flexible substrate for the purposes of the present invention. Furthermore, the photovoltaic cell of the invention preferably comprises a layer of molybdenum or tungsten having a preferred thickness of from 0.1 to 2 μm which is used as barrier layer and for aiding the exit of electrons into the absorber and as back contact in the case of glass as substrate.

The invention further provides a process for producing the photovoltaically active semiconductor material of the invention and/or a photovoltaic cell according to the invention, which comprises the steps:
production of a layer of the semiconductor material of the formula Zn₁₋ₓMgₓTe or ZnTe and
introduction of a dopant MₙTeₘ or MeₐM_{b} into the layer,
   where M is at least one element selected from the group consisting of Si, Ge, Sn, Pb, Sb and Bi and Me is at least one element selected from the group consisting of Mg and Zn, where
x=0 to 0.5
y=0.0001 to 0.05
n=1 to 2
m=0.5 to 4
a=1 to 5 and
b=1 to 3.

The layer produced from the semiconductor material of the formula Zn₁₋ₓMgₓTe or ZnTe preferably has a thickness of from 0.1 to 20 μm, more preferably from 0.1 to 10 μm, particularly preferably from 0.3 to 3 μm. This layer is preferably produced by at least one deposition method selected from the group consisting of sputtering, electrochemical deposition or electroless deposition. The term sputtering refers to the ejection of clusters comprising from about 10 to 10 000 atoms from a sputtering target serving as electrode by means of accelerated ions and the deposition of the ejected material on a substrate. The layers of the semiconductor material of the formula (I) and/or (II) which are produced by the process of the invention are particularly preferably produced by sputtering, because sputtered layers have a higher quality. However, the deposition of zinc and the dopant M and, if appropriate, Mg on a suitable substrate and subsequent reaction with a Te vapor at temperatures below 400° C. in the presence of hydrogen is also possible. A further suitable method is electrochemical deposition of ZnTe to produce a layer and the subsequent doping of this layer with a dopant to produce a semiconductor material of the formula (I) and/or (II).

Particular preference is given to introducing the dopant metal during the synthesis of the zinc telluride in evacuated fused silica vessels. In this case, zinc, if appropriate magnesium, tellurium and the dopant metal or mixtures of dopant metals are introduced into the fused silica vessel, the fused silica vessel is evacuated and flame sealed under reduced pressure. The fused silica vessel is then heated in a furnace, firstly quickly to about 400° C. because no reaction takes place below the melting point of Zn and Te. The temperature is then increased more slowly at rates of from 20 to 100° C./h to from 800 to 1200° C., preferably to from 1000 to 1100° C. The formation of the solid state structure takes place at this temperature. The time necessary for this is from 1 to 100 h, preferably from 5 to 50 h. Cooling then takes place. The content of the fused silica vessel are broken up with exclusion of moisture to particle sizes of from 0.1 to 1 mm and these particles are then comminuted, e.g. in a ball mill, to particle sizes of from 1 to 30 μm, preferably from 2 to 20 μm. Sputtering targets are then produced from the resulting powder by hot pressing at from 300 to 1200° C., preferably at from 400 to 700° C., and pressures of from 5 to 500 MPa, preferably at from 20 to 200 MPa. The pressing times are from 0.2 to 10 h, preferably from 1 to 3 h.

In a preferred embodiment of the process of the invention for producing a photovoltaically active semiconductor material and/or a photovoltaic cell, a sputtering target of the formula (Zn₁₋ₓMgₓTe)_{1-y}(MₙTeₘ)_{y} and/or (ZnTe)_{1-y}(MeₐM_{b})_{y} is produced by
a) reaction of Zn, Te, M and, if appropriate, Mg in evacuated fused silica tubes at from 800 to 1200° C., preferably from 1000 to 1100° C., for from 1 to 100 hours, preferably from 5 to 50 hours, to give a material,
b) milling of the material after cooling with substantial exclusion of atmospheric oxygen and moisture to give a powder having particle sizes of from 1 to 30 μm, preferably from 2 to 20 μm, and
c) hot pressing of the powder at temperatures of from 300 to 1200° C., preferably from 400 to 700° C., pressures of from 5 to 500 MPa, preferably from 20 to 200 MPa, and pressing times of from 0.2 to 10 hours, preferably from 1 to 3 hours.

In a further embodiment of the process of the invention for producing a photovoltaically active semiconductor material and/or a photovoltaic cell, a sputtering target of the formula Zn₁₋ₓMg_{x′}Te and/or ZnTe is produced by
a) reaction of Zn, Te and, if appropriate, Mg in evacuated fused silica tubes at from 800 to 1200° C., preferably from 1000 to 1100° C., for from 1 to 100 hours, preferably from 5 to 50 hours, to give a material,
b) milling of the material after cooling with substantial exclusion of atmospheric oxygen and moisture to give a powder having particle sizes of from 1 to 30 μm, preferably from 2 to 20 μm, and
c) hot pressing of the powder at temperatures of from 300 to 1200° C., preferably from 400 to 700° C., pressures of from 5 to 500 MPa, preferably from 20 to 200 MPa, and pressing times of from 0.2 to 10 hours, preferably from 1 to 3 hours.

The dopants MₙTeₘ and MeₐM_{b} can be introduced into the Zn₁₋ₓMg_{x′}Te and/or ZnTe after sputtering. However, the material obtained in step a) is preferably milled with the dopant MₙTeₘ or MeₐM_{b} in step b). Here, part of the dopant can react with the zinc telluride in the form of reaction milling and be incorporated into the host lattice. The doped material of the invention of the formula (I) or (II) or combinations thereof is then formed during hot pressing in step c).

In further process steps known to those skilled in the art, the photovoltaic cell of the invention is finished by means of the process of the invention.

### EXAMPLES

The examples were carried out using powders rather than thin layers. The measured properties of the semiconductor materials comprising dopants, e.g. energy gap, conductivity or Seebeck coefficient, are not thickness-dependent and are therefore equally valid.

The compositions indicated in the table of results were produced in evacuated fused silica tubes by reaction of the elements in the presence of dopant metals. For this purpose, the elements having a purity of in each case better than 99.99% were weighed into fused silica tubes, the residual moisture was removed by heating under reduced pressure and the tubes were flame sealed under reduced pressure. The tubes were heated over a period of 20 h from room temperature to 1100° C. in a slanting tube furnace and the temperature was then maintained at 1100° C. for 10 h. The furnace was then switched off and allowed to cool.

After cooling, the tellurides produced in this way were comminuted in an agate mortar to produce powders having particle sizes of less than 30 μm. These powders were pressed at room temperature under a pressure of 3000 kp/cm² to produce disks having a diameter of 13 mm.

A disk having a grayish black color and a slight reddish sheen was obtained in each case.

In a Seebeck experiment, the materials were heated to 130° C. on one side while the other side was maintained at 30° C. The open-circuit voltage was measured by means of a voltmeter. This value divided by 100 gives the mean Seebeck coefficient indicated in the table of results.

In a second experiment, the electrical conductivity was measured. The absorptions in the optical reflection spectrum indicated the values of the band gap between valence band and conduction band as from 2.2 to 2.3 eV and in each case an intermediate level at from 0.8 to 1.3 eV.

Table of results

| | Seebeck | Electrical |
|---|---|---|
| | coefficient | conductivity |
| Composition | μV/° C. | S/cm |
| (Zn_{0.97}Mg_{0.03}Te)_{0.99}(Sb₂Te₃)_{0.01} | 220 | 1 |
| (Zn_{0.98}Mg_{0.02}Te)_{0.96}(GeTe)_{0.04} | 160 | 0.1 |
| (Zn_{0.96}Mg_{0.04}Te)_{0.98}(PbTe)_{0.02} | 200 | 0.3 |
| (ZnTe)_{0.98}(Sb₂Te₃)_{0.02} | 100 | 2.5 |
| (ZnTe)_{0.98}(GeTe)_{0.02} | 220 | 0.2 |
| (ZnTe)_{0.98}(SnTe)_{0.02} | 170 | 0.5 |
| (ZnTe)_{0.995}(Bi₂Te₃)_{0.005} | 120 | 0.1 |
| (ZnTe)_{0.99}(Mg₃Sb₂)_{0.01} | 90 | 4 |
| (ZnTe)_{0.99}(Mg₃Bi₂)_{0.01} | 70 | 3 |
| (ZnTe)_{0.98}(Sb₂Te₃)_{0.01}(Mg₃Sb₂)_{0.01} | 80 | 0.4 |
| (ZnTe)_{0.98}(Sb₂Te₃)_{0.01}(Zn₃Sb₂)_{0.01} | 70 | 0.2 |

The latter two compositions in the results table are examples of combinations of semiconductor materials according to the invention of the formula (I) and of the formula (II) and can be described by the formula (III):

(Zn₁₋ₓMgₓTe)₁₋ᵤ₋ᵥ(MₙTeₘ)ᵤ(MeₐM_{b})ᵥ (III)

where u+v=y

1. A photovoltaically active semiconductor material of the formula (I), of the formula (II) or of a combination thereof:
(Zn₁₋ₓMgₓTe)_{1-y}(MₙTeₘ)_{y} and (I)
(ZnTe)_{1-y}(MeₐM_{b})_{y}, wherein (II)
MₙTeₘ and MeₐM_{b} are each a dopant in which M is at least one element selected from the group consisting of silicon, germanium, tin, lead, antimony and bismuth, and Me is at least one element selected from the group consisting of magnesium and zinc, and
x=0 to 0.5
y=0.0001 to 0.05
n=1 to 2
m=0.5 to 4
a=1 to 5 and
b=1 to 3.

2. A photovoltaic cell comprising a photovoltaically active semiconductor material, wherein the photovoltaically active semiconductor material is a material of the formula (I), of the formula (II) or of a combination thereof:
(Zn₁₋ₓMgₓTe)_{1-y}(MₙTeₘ)_{y} and (I)
(ZnTe)_{1-y}(MeₐM_{b})_{y}, wherein (II)
MₙTeₘ and MeₐM_{b} are each a dopant in which M is at least one element selected from the group consisting of silicon, germanium, tin, lead, antimony and bismuth, and Me is at least one element selected from the group consisting of magnesium and zinc, and
x=0 to 0.5
y=0.0001 to 0.05
n=1 to 2
m=0.5 to 4
a=1 to 5 and
b=1 to 3.

3. The photovoltaic cell according to claim 2, wherein the dopant is at least one compound selected from the group consisting of Si₃Te₃, GeTe, SnTe, PbTe, Sb₂Te₃, Bi₂Te₃, Mg₂Si, Mg₂Ge, Mg₂Sn, Mg₂Pb, Mg₃Sb₂, Mg₃Bi₂, ZnSb, Zn₃Sb₂ and Zn₄Sb₃.

4. The photovoltaic cell according to claim 2, comprising at least one p-conducting absorber layer of the material of the formula (I), of the formula (II) or of a combination thereof.

5. The photovoltaic cell according to claim 2, comprising an n conducting transparent layer comprising at least one semiconductor material selected from the group consisting of indium-tin oxide, fluorine-doped tin oxide, antimony-doped zinc oxide, gallium-doped zinc oxide, indium-doped zinc oxide and aluminum-doped zinc oxide.

6. The photovoltaic cell according to claim 2, comprising at least one p-conducting layer of the material of the formula (I), of the formula (II) or of a combination thereof, at least one n-conducting layer and a substrate which is a glass pane coated with an electrically conductive material, a flexible metal foil or a flexible metal sheet.

7. A process for producing a photovoltaically active semiconductor material according to claim 1 comprising producing a layer of a semiconductor material of the formula Zn₁₋ₓMgₓTe or ZnTe and introducing a dopant MₙTeₘ or MeₐM_{b} into the layer.

8. The process according to claim 7, wherein the layer of the semiconductor material has a thickness of from 0.1 to 20 μm.

9. The process according to claim 7, wherein the layer is produced by means of at least one deposition process selected from the group consisting of sputtering, electrochemical deposition and electroless deposition.

10. The process according to claim 7, wherein a sputtering target of the formula Zn₁₋ₓMgₓTe, ZnTe, (Zn₁₋ₓ(MgₓTe)_{1-y}(MₙTeₘ)_{y} or (ZnTe)_{1-y}(MeₐM_{b})_{y} is produced by
a) reacting Zn, Te and, if appropriate, Mg and M in evacuated fused silica tubes at from 800 to 1200° C., for from 1 to 100 hours to yield a material,
b) milling the material after cooling with a substantial exclusion of atmospheric oxygen and moisture to yield a powder having particle sizes of from 1 to 30 μm, and
c) hot pressing of the powder at temperatures of from 300 to 1200° C., pressures of from 5 to 500 MPa and a pressing time of from 0.2 to 10 hours.

11. The process according to claim 10, wherein the material obtained by reaction of Zn, Te and, if appropriate, Mg in a) is milled with the dopant MₙTeₘ or MeₐM_{b} in b).
